(19) United States
(12) Patent Application Publication
(10) Pub. No.: US 2011/0056738 A1
(43) Pub. Date: Mar. 10, 2011

(54) PACKAGE SUBSTRATE AND MANUFACTURING METHOD THEREOF

(75) Inventor: Wen Hung Hu, Hsin-Chu (TW)

(73) Assignee: PHOENIX PRECISION TECHNOLOGY CORPORATION, Hsin-Chu (TW)

(21) Appl. No.: 12/554,087

(22) Filed: Sep. 4, 2009

(51) Int. Cl. H05K 1/11; G03F 7/20; B23K 26/00; C25D 5/02

(52) U.S. Cl. 174/261; 430/311; 219/121.69; 205/125

(57) ABSTRACT

A package substrate and a manufacturing method thereof are provided, including: forming a solder mask on a package substrate body having a plurality of conductive pads; forming a plurality of first-step openings in the solder mask by exposure and development; forming a plurality of second-step openings in the solder mask by a laser-based or plasma-based drilling process; and removing a solder mask foot from the bottom of each of the first-step openings so as to expose large surface areas of the conductive pads. Hence, the contact area between a conductive element and a corresponding one of the conductive pads is large enough to enhance bonding and electrical connection therebetween.

### BACKGROUND OF THE INVENTION

1. Field of the Invention

The present invention relates to semiconductor devices and methods of manufacturing the same, and more particularly, to a package substrate and a manufacturing method thereof.

2. Description of the Prior Art

In the early 1960s, IBM developed flip-chip package technology. Unlike wire-bonding techniques, flip-chip techniques not only entail electrically connecting a semiconductor chip and a substrate by solder bumps instead of bonding wires and thereby advantageously increase packaging density and downsize package components, but also dispense with long bonding wires and thereby advantageously shorten the distance of transmission of signals and enhance electrical performance.

Existing flip-chip techniques involve providing a plurality of electrode pads on a semiconductor chip having an integrated circuit (IC) therein, providing a plurality of conductive pads on a package substrate so as for the conductive pads to correspond in position to the electrode pads, providing solder bumps or other conductive materials between the semiconductor chip and the package substrate as appropriate, thereby allowing the semiconductor chip to be face-down mounted on the package substrate (that is, the electrode pad-disposed electrical contact surface of the semiconductor chip faces downward), wherein the solder bumps or conductive materials enable electrical input/output (I/O) and mechanical connection between the semiconductor chip and the package substrate.

Referring to FIG. 1A through FIG. 1E, cross-sectional views of forming a conductive material on conductive pads of a package substrate by stencil printing in a known manner are shown. Referring to FIG. 1A, a solder mask 11 is formed on a package substrate body 10 with a plurality of conductive pads 101 provided thereon, a plurality of openings 110 are formed in the solder mask 11 for exposing the conductive pads 101; After a patterning process is performed on the solder mask 11 and the openings 110 thereof, a solder mask foot 110a is formed on each of the conductive pads 101 exposed from each corresponding one of the openings 110. Referring to FIG. 1B, a stencil 12 with open areas 120 is positioned above the solder mask 11 on the package substrate body 10 so as for the open areas 120 to correspond in position to the conductive pads 101. Referring to FIG. 1C, a conductive material 13 is formed in the open areas 120 of the stencil 12 by printing. Referring to FIG. 1D, the stencil 12 is removed to expose the conductive material 13. Referring to FIG. 1E, a conductive element 13′ is formed on the conductive pads 101 by a reflow process and configured for electrical connection of the conductive pads 101 and an external electronic device. Despite the presence of the solder mask foot 110a on each of the conductive pads 101 exposed from each corresponding one of the openings 110, the openings 110 formed in the solder mask 11 by printing are large enough for a relatively large area of the conductive pads 101 to be exposed and thereby the bonding between the conductive element 13′ and the conductive pads 101 to continue unabated.

Nonetheless, the open areas 120 of the stencil 12 dwindle as the conductive pads 101 are provided at an increasingly high density, and in consequence the open areas 120 are unlikely to be filled with the conductive material 13; hence, it is difficult to form the conductive element 13′ on the conductive pads 101 of a high-density package substrate by printing.

Referring to FIG. 2A through FIG. 2G, in an attempt to overcome the aforesaid drawbacks of known stencil printing techniques, manufacturers proposed electroplating a conductive material to a package substrate. Referring to FIG. 2A, a package substrate body 10 that has undergone a wiring process and has at least a surface thereof having the conductive pads 101 formed thereon is provided. Referring to FIG. 2B, the solder mask 11 is formed on the package substrate body 10. Referring to FIG. 2C, the openings 110 are formed in the solder mask 11 by a patterning process that entails exposure and development so as for the openings 110 thus formed to correspond in position to and expose the conductive pads 101, respectively, and the solder mask foot 110a is left behind on each of the conductive pads 101 exposed from each corresponding one of the openings 110. Referring to FIG. 2D, a conductive layer 21 is formed on the solder mask 11 and the openings 110 thereof, and a resist layer 22 is formed on the conductive layer 21 to thereby allow a plurality of resist layer openings 220 to be formed in the resist layer 22 for exposing the openings 110, the periphery of the openings 110, and the conductive layer 21 covering the conductive pads 101. Referring to FIG. 2E, in an electroplating process wherein the conductive layer 21 functions as a path of electric current due to conductive characteristics of the conductive layer 21, a conductive material 23 is electroplated to the conductive layer 21 exposed from the resist layer openings 220. Referring to FIG. 2F, the resist layer 22 and the conductive layer 21 thereunder are removed to further expose the conductive material 23. Referring to FIG. 2G, the conductive material 23 is turned into a conductive element 23′ by a reflow process to facilitate electrical connection with an external electronic device.

Referring to FIG. 2C, with the openings 110 being formed in the solder mask 11 by a patterning process that entails exposure and development, the solder mask foot 110a is left behind on each of the conductive pads 101 exposed from each corresponding one of the openings 110, and thus each of the openings 110 narrows toward the bottom thereof; subsequently, the contact area between the conductive element 23′ and a corresponding one of the conductive pads 101 is so small as to compromise electrical connection between the conductive element 23′ and the corresponding one of the conductive pads 101 or weaken the bonding between the conductive element 23′ and the corresponding one of the conductive pads 101 and thereby compromise electrical connection therebetween.

Accordingly, it is imperative to provide a package substrate having a conductive element to improve electrical connection between the conductive element and conductive pads.

### SUMMARY OF THE INVENTION

In view of the drawbacks of the prior art, it is an objective of the present invention to provide a package substrate and a manufacturing method thereof so as to reinforce a conductive element and thereby augment bonding thereof and enhance the quality of electrical connection.

Another objective of the present invention is to provide a package substrate and a manufacturing method thereof so as to make fabrication of the conductive element simpler.

To achieve the above and other objectives, the present invention provides a package substrate, comprising: a package substrate body with at least a surface thereof having a plurality of conductive pads thereon; a solder mask provided on the package substrate body and the conductive pads and provided therein with a plurality of first-step openings and a plurality of second-step openings in communication with the first-step openings so as for the conductive pads to correspond in position to and be exposed from the first-step openings and the second-step openings, the second-step openings being above the first-step openings, respectively, and each having a bottom rim in contact with a corresponding one of the first-step openings and a top rim, the bottom rim being of a smaller diameter than the top rim and of the same diameter as the corresponding one of the first-step openings; and a conductive material provided in the first-step and second-step openings of the solder mask.

A sloped wall or a curved wall is defined by and provided between the top rim and the bottom rim of each of the second-step openings.

The package substrate of the present invention further comprises a conductive layer disposed between the conductive pads and the conductive material. The conductive material is solder, thereby allowing a conductive element to be made of the conductive material by a reflow process. Alternatively, the conductive material is copper, silver, nickel, gold, or platinum.

The present invention further provides a method of manufacturing a package substrate, comprising the steps of: providing a package substrate body having at least a surface, the at least a surface having a plurality of conductive pads formed thereon; forming a solder mask on the package substrate body and conductive pads; forming in the solder mask a plurality of first-step openings corresponding in position to and exposing a portion of the conductive pads; forming in the solder mask a plurality of second-step openings corresponding in position to the first-step openings, the second-step openings being above the first-step openings, respectively, and each having a bottom rim in contact with a corresponding one of the first-step openings and a top rim, the bottom rim being of a smaller diameter than the top rim and of the same diameter as the corresponding one of the first-step openings; and forming a conductive material in the first-step and second-step openings of the solder mask.

As regards the method, a sloped wall or a curved wall is defined by and provided between the top rim and the bottom rim of each of the second-step openings.

The method further comprises the step of forming the first-step openings by exposure and development and the step of forming the second-step openings by a laser-based or plasma-based drilling process.

The conductive material is solder, thereby allowing a conductive element to be made of the conductive material by a reflow process. Alternatively, the conductive material is copper, silver, nickel, gold, or platinum.

Regarding the method of manufacturing the package substrate of the present invention, the conductive material is formed by electroplating and by the steps of: forming a conductive layer on the solder mask and in the first-step and second-step openings; forming a resist layer on the conductive layer and forming a plurality of resist layer openings corresponding in position to the first-step and second-step openings in the resist layer for exposing the conductive layer on the conductive pads and in the first-step and second-step openings; electroplating the conductive material to the conductive layer exposed from the resist layer openings; and removing the resist layer and the conductive layer thereunder to expose the conductive material.

Also, the conductive material is formed by stencil printing and by the steps of: positioning above the solder mask a stencil having a plurality of open areas so as for the open areas of the stencil to correspond in position to the first-step and second-step openings, respectively; filling the open areas and the first-step and second-step openings with the conductive material; and removing the stencil to expose the conductive material.

Alternatively, the conductive material is provided in the form of solder balls received in the first-step and second-step openings, respectively.

Accordingly, the present invention provides a package substrate and a method of manufacturing the same. The method comprises the steps of: covering a package substrate body having a plurality of conductive pads thereon with a solder mask; forming a plurality of first-step openings in the solder mask by exposure and development for exposing the conductive pads; forming a plurality of second-step openings in the solder mask by a laser-based or plasma-based drilling process; and removing a solder mask foot from the bottom of each of the first-step openings so as to expose large surface areas of the conductive pads. Hence, the contact area between a conductive element and a corresponding one of the conductive pads is large enough to enhance bonding and electrical connection therebetween. Also, with the second-step openings outmatching the first-step openings in diameter, a conductive material can be formed in the first-step and second-step openings by printing or ball implantation so as to make fabrication of the conductive element simpler.

### BRIEF DESCRIPTION OF THE DRAWINGS

To enable persons skilled in the art to gain insight into technical features and effects of the present invention, the present invention is hereunder illustrated with preferred embodiments in conjunction with the accompanying drawings, wherein:

FIG. 1A through FIG. 1E are cross-sectional views of forming a conductive material on a package substrate by printing in a known manner;

FIG. 2A through FIG. 2G are cross-sectional views of forming a conductive material on a package substrate by electroplating in a known manner;

FIG. 3A through FIG. 3G are cross-sectional views of a first embodiment of a method of manufacturing a package substrate according to the present invention;

FIG. 3G′ is a cross-sectional view of another embodiment of the method illustrated by FIG. 3G;

FIG. 4A through FIG. 4D are cross-sectional views of a second embodiment of a method of manufacturing a package substrate according to the present invention; and

FIG. 5A and FIG. 5B are cross-sectional views of a third embodiment of a method of manufacturing a package substrate according to the present invention.

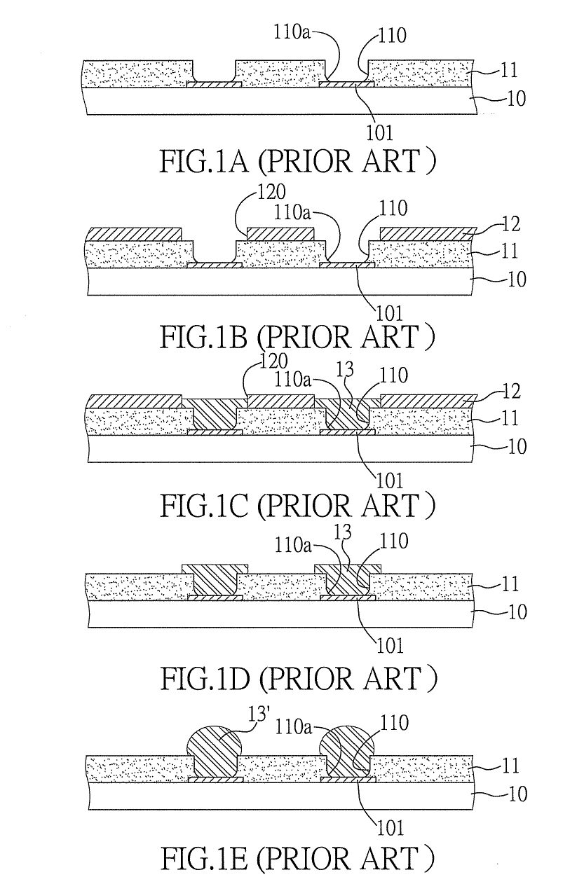

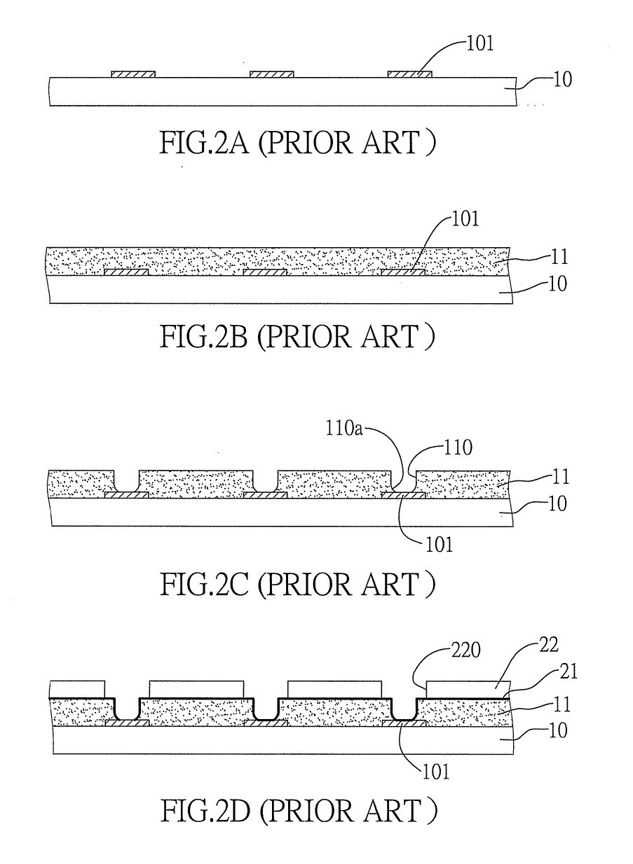

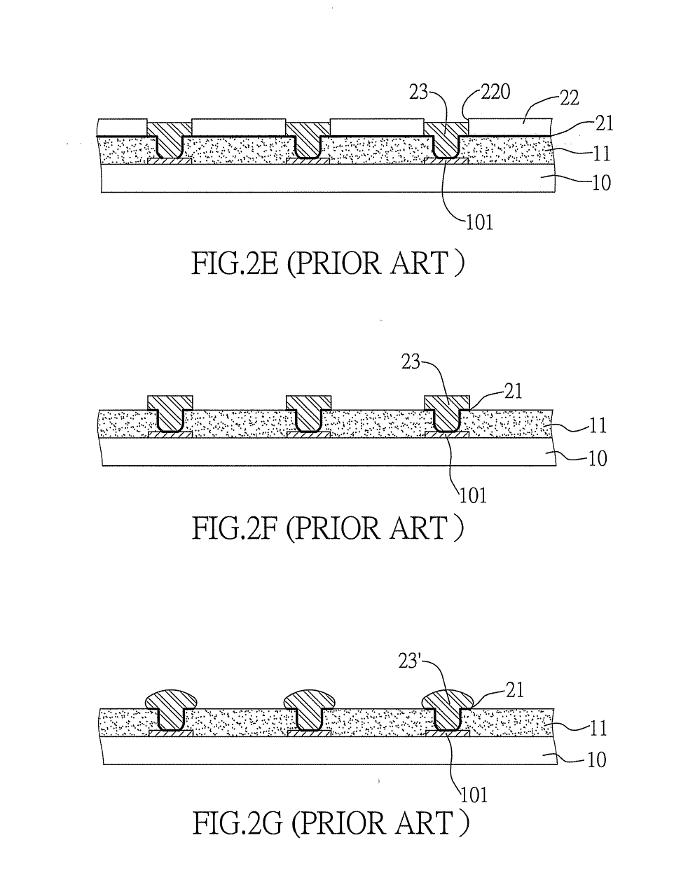

### DETAILED DESCRIPTION OF THE EMBODIMENTS

### First Embodiment

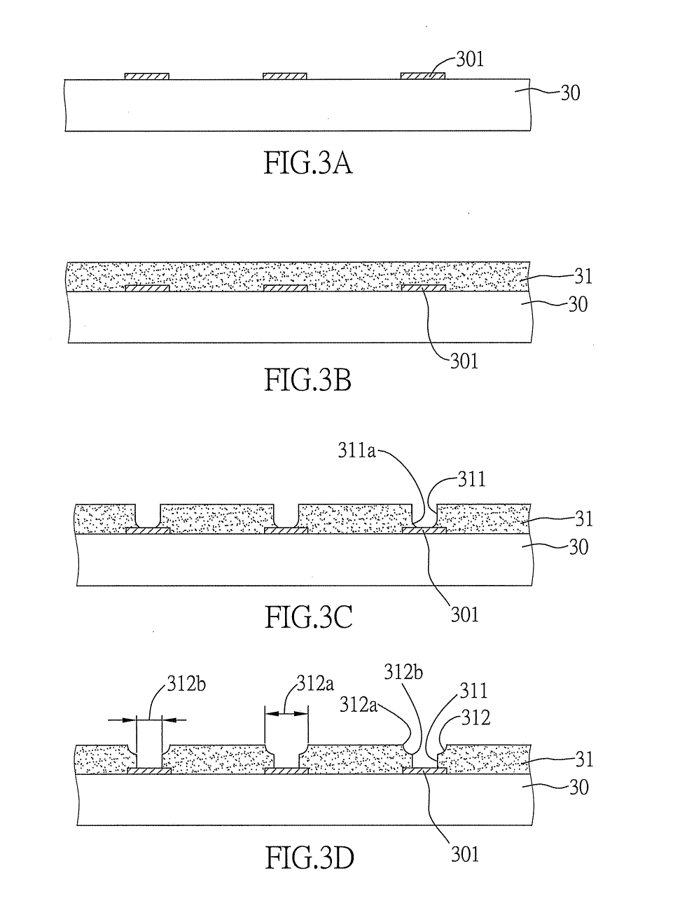

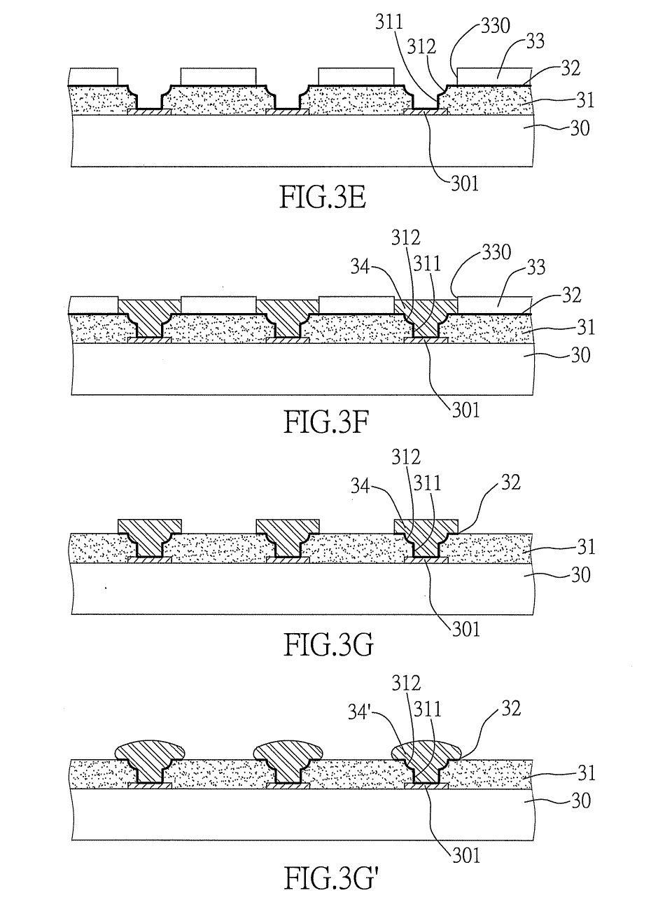

Referring to FIG. 3A through FIG. 3G, cross-sectional views of a first embodiment of a package substrate and a method of manufacturing the package substrate according to the present invention are shown.

Referring to FIG. 3A, a package substrate body 30 with at least a surface thereof having a plurality of conductive pads 301 formed thereon is provided.

Referring to FIG. 3B, a solder mask 31 is formed on the package substrate body 30 and the conductive pads 301.

Referring to FIG. 3C, a plurality of first-step openings 311 corresponding in position to and exposing portions of the conductive pads 301, respectively, are formed in the solder mask 31 by exposure and development, and yet a solder mask foot 311a is left behind in the bottom of each of the first-step openings 311.

Referring to FIG. 3D, a plurality of second-step openings 312 corresponding in position to the first-step openings 311 are formed in the solder mask 31 by a laser-based or plasma-based drilling process. Each of the second-step openings 312 has a bottom rim 312b in contact with a corresponding one of the first-step openings 311 and a top rim 312a. The top rim 312a is of a larger diameter than the bottom rim 312b. The bottom rim 312b is of the same diameter as the corresponding one of the first-step openings 311. The first-step openings 311 and portions of the conductive pads 301 correspond in position to and are exposed from the second-step openings 312, respectively, As shown in the drawing, the solder mask foot 311a is removed from the bottom of each of the first-step openings 311 by the laser-based or plasma-based drilling process.

A sloped wall or a curved wall is defined by and provided between the top rim 312a and the bottom rim 312b of each of the second-step openings 312. Defined by and provided between the top rim 312a and the bottom rim 312b is preferably a curved wall, as shown in the drawing.

Refer to FIG. 3E for a better understanding of the following steps of manufacturing the package substrate according to the present invention as follows: a conductive layer 32 is formed on the solder mask 31 and the walls of the first-step and second-step openings 311, 312; a resist layer 33 is formed on the conductive layer 32; a plurality of resist layer openings 330 corresponding in position to the first-step and second-step openings 311, 312 of the solder mask 31, respectively, are formed in the resist layer 33 for exposing portions of the conductive pads 301 and portions of the conductive layer 32 exposed from the first-step and second-step openings 311, 312.

Referring to FIG. 3F, a conductive material 34 is electroplated to the conductive layer 32 exposed from the resist layer openings 330, by an electroplating process wherein the conductive layer 32 functions as a path of electric current due to conductive characteristics of the conductive layer 32.

Referring to FIG. 3G and FIG. 3G′, the resist layer 33 and the conductive layer 32 thereunder are removed to expose the conductive material 34, wherein the conductive material 34 is copper, silver, nickel, gold, or platinum, as shown in FIG. 3G. Alternatively, the conductive material 34 is solder such that a conductive element 34′ can be made of the conductive material 34 by a reflow process to thereby allow the conductive pads 301 to be electrically connected with an external electronic device as shown in FIG. 3G′.

The present invention further provides a package substrate, comprising: a package substrate body 30 with at least a surface thereof having a plurality of conductive pads 301 formed thereon; a solder mask 31 provided on the package substrate body 30 and the conductive pads 301 and provided therein with a plurality of first-step openings 311 and a plurality of second-step openings 312 in communication with the first-step openings 311 so as for the conductive pads 301 to correspond in position to and be exposed from the first-step openings 311 and the second-step openings 312, the second-step openings 312 being above the first-step openings 311, respectively, and each having a bottom rim 312b in contact with a corresponding one of the first-step openings 311 and a top rim 312a, the bottom rim 312b being of a smaller diameter than the top rim 312a and of the same diameter as the corresponding one of the first-step openings 311; and a conductive material 34 provided in the first-step and second-step openings 311, 312 of the solder mask 31.

The package substrate of the present invention further comprises a conductive layer 32 disposed between the conductive pads 301 and the conductive material 34. The conductive material 34 comprises one selected from the group consisting of copper, silver, nickel, gold, and platinum. Alternatively, the conductive material 34 is solder, thereby allowing a conductive element 34′ to be made of the conductive material 34 by a reflow process and configured to electrically connect the conductive pads 301 and an external electronic device.

### Second Embodiment

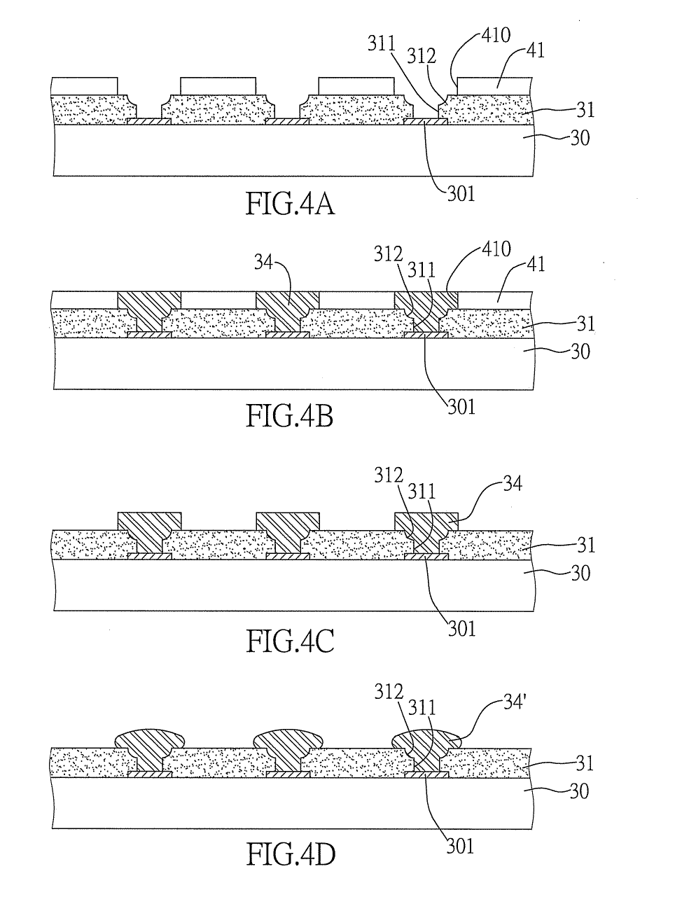

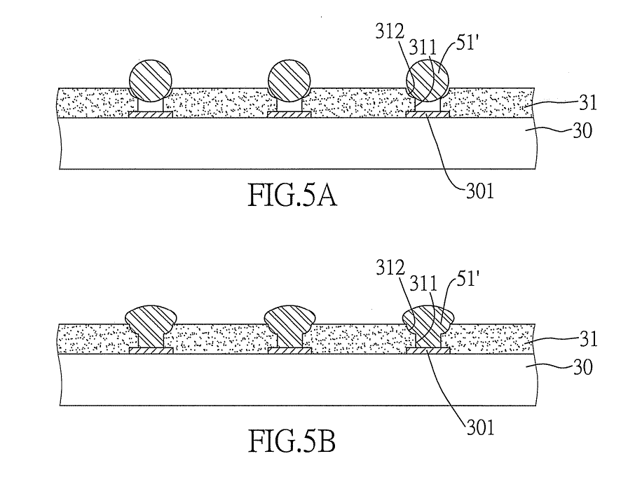

Referring to FIG. 4A through FIG. 4D, cross-sectional views of a second embodiment of a method of manufacturing a package substrate according to the present invention are shown. The second embodiment differs from the first embodiment in that, in the second embodiment, the conductive material is formed by stencil printing.

Referring to FIG. 4A, a structure shown in FIG. 3D is provided, a stencil 41 with a plurality of open areas 410 is positioned over the solder mask 31 so as for the open areas 410 of the stencil 41 to correspond in position to the first-step and second-step openings 311, 312 of the solder mask 31.

Referring to FIG. 4B, the open areas 410 and the first-step and second-step openings 311, 312 are filled with the conductive material 34, using a roller or a spray, so as to form the conductive material 34 on each of the conductive pads 301 exposed from each corresponding one of the first-step and second-step openings 311, 312.

Referring to FIG. 4C, the stencil 41 is removed so as to expose the conductive material 34.

Referring to FIG. 4D, the conductive material 34 is turned into a conductive element 34′ by a reflow process for electrical connection of the conductive pads 301 and an external electronic device.

### Third Embodiment

Referring to FIG. 5A and FIG. 5B, cross-sectional views of a third embodiment of a method of manufacturing a package substrate according to the present invention are shown. The third embodiment differs from the first and second embodiments in that, in the third embodiment, the conductive material is provided in the form of balls.

Referring to FIG. 5A, the structure shown in FIG. 3D is provided, and a plurality of solder balls 51 are received in the first-step and second-step openings 311, 312 of the solder mask 31.

Referring to FIG. 5B, the solder balls 51 are turned into a conductive element 51′ by a reflow process for electrical connection of the conductive pads and an external electronic device.

In conclusion, the present invention provides a package substrate and a method of manufacturing the same. The method comprises the steps of: forming a solder mask on a package substrate body and a plurality of conductive pads thereon; forming a plurality of first-step openings in the solder mask by exposure and development; forming a plurality of second-step openings in the solder mask by a laser-based or plasma-based drilling process; removing a solder mask foot from the bottom of each of the first-step openings so as to expose large surface areas of the conductive pads. Hence, the contact area between a conductive element and a corresponding one of the conductive pads is large enough to enhance the bonding and electrical connection therebetween. Also, with the second-step openings outmatching the first-step openings in diameter, a conductive material can be formed in the first-step and second-step openings by printing or ball implantation so as to make fabrication of the conductive element simpler.

The foregoing specific embodiments are only illustrative of the features and functions of the present invention but are not intended to restrict the scope of the present invention. It is apparent to those skilled in the art that all equivalent modifications and variations made in the foregoing embodiments according to the spirit and principle in the disclosure of the present invention should fall within the scope of the appended claims.

What is claimed is:

1. A package substrate, comprising:
a package substrate body with at least a surface thereof having a plurality of conductive pads thereon;
a solder mask provided on the package substrate body and the conductive pads and provided therein with a plurality of first-step openings and a plurality of second-step openings in communication with the first-step openings so as for the conductive pads to be exposed from the first-step openings and the second-step openings, the second-step openings being above the first-step openings, respectively, and each having a bottom rim in contact with a corresponding one of the first-step openings and a top rim, the bottom rim being of a smaller diameter than the top rim and of a same diameter as the corresponding one of the first-step openings; and
a conductive material provided in the first-step and second-step openings of the solder mask.

2. The package substrate of claim 1, further comprising a conductive layer disposed between the conductive pads and the conductive material.

3. The package substrate of claim 1, wherein the conductive material is solder.

4. The package substrate of claim 3, wherein in a reflow process the conductive material is turned into a conductive element for electrical connection with the conductive pads.

5. The package substrate of claim 1, wherein the conductive material comprises one selected from the group consisting of copper, silver, nickel, gold, and platinum.

6. The package substrate of claim 1, wherein a sloped wall or a curved wall is defined by and provided between the top rim and the bottom rim of each of the second-step openings.

7. A method of manufacturing a package substrate, comprising the steps of:
providing a package substrate body having at least a surface, the at least a surface having a plurality of conductive pads formed thereon;
forming a solder mask on the package substrate body and conductive pads;
forming in the solder mask a plurality of first-step openings corresponding in position to and exposing a portion of the conductive pads;
forming a plurality of second-step openings in the solder mask, the second-step openings being above the first-step openings, respectively, and each having a bottom rim in contact with a corresponding one of the first-step openings and a top rim, the bottom rim being of a smaller diameter than the top rim and of a same diameter as the corresponding one of the first-step openings; and
forming a conductive material in the first-step and second-step openings of the solder mask.

8. The method of claim 7, wherein the first-step openings are formed by exposure and development.

9. The method of claim 7, wherein the second-step openings are formed by a laser-based or plasma-based drilling process.

10. The method of claim 7, wherein the conductive material is solder.

11. The method of claim 10, wherein in a reflow process the conductive material is turned into a conductive element for electrical connection with the conductive pads.

12. The method of claim 7, wherein the conductive material comprises one selected from the group consisting of copper, silver, nickel, gold, and platinum.

13. The method of claim 7, wherein the conductive material is formed by electroplating and by the steps of:
forming a conductive layer on the solder mask and in the first-step and second-step openings;
forming a resist layer on the conductive layer and forming a plurality of resist layer openings corresponding in position to the first-step and second-step openings in the resist layer for exposing the conductive layer on the conductive pads and in the first-step and second-step openings;
electroplating the conductive material to the conductive layer exposed from the resist layer openings; and
removing the resist layer and the conductive layer thereunder to expose the conductive material.

14. The method of claim 7, wherein the conductive material is formed by stencil printing and by the steps of:
positioning above the solder mask a stencil having a plurality of open areas so as for the open areas of the stencil to correspond in position to the first-step and second-step openings, respectively;
filling the open areas and the first-step and second-step openings with the conductive material; and
removing the stencil to expose the conductive material.

15. The method of claim 7, wherein the conductive material is provided in form of a plurality of solder balls received in the first-step and second-step openings.

16. The method of claim 7, wherein a sloped wall or a curved wall is defined by and provided between the top rim and the bottom rim of each of the second-step openings.
